(19) United States
(12) Patent Application Publication
(10) Pub. No.: US 2026/0095016 A1
(43) Pub. Date: Apr. 2, 2026

(54) TECHNOLOGIES FOR A PHOTON PAIR SOURCE ON AN INTEGRATED PHOTONIC DIE

(71) Applicant: Intel Corporation, Santa Clara, CA (US)

(72) Inventors: Xiaoxi Wang, Mountain View, CA (US); Ranjeet Kumar, Milpitas, CA (US); Haisheng Rong, Pleasanton, CA (US)

(73) Assignee: Intel Corporation, Santa Clara, CA (US)

(21) Appl. No.: 18/899,961

(22) Filed: Sep. 27, 2024

(51) Int. Cl. H01S 3/30; G02B 6/42; H01S 5/026; H01S 5/04; H01S 5/50

(52) U.S. Cl. CPC H01S 3/302; G02B 6/428; H01S 5/026; H01S 5/041; H01S 5/5054

(57) ABSTRACT

Technologies for a photon pair source integrated on a photonic die are disclosed. In an illustrative embodiment, a photonic die includes an integrated semiconductor laser. The integrated semiconductor laser pumps a Raman laser on the same die. The Raman laser has much lower noise near the laser peak compared to the semiconductor laser, due to a smaller gain bandwidth and less amplified stimulated emission. Due to the low noise, the Raman laser can be used to pump a spontaneous four-wave mixing (SFWM) source directly, without off-chip filtering required. The SFWM source can generate entangled photons with a high signal-to-noise ratio, with applications for quantum cryptography, quantum computing, and other quantum information processing tasks.

### BACKGROUND

Quantum light sources, such as single photons or photon pairs, can be used for a range of optical quantum systems, such as secure communication, information processing, and quantum computing. High-quality sources, such as pairs of entangled photons with a high signal-to-noise ratio, are required for a high level of performance in such applications. One source of photon pairs that is compatible with high-volume manufacturing is spontaneous four-wave mixing in silicon photonics. However, such approaches typically require off-chip filtering of noisy pump lasers in order to achieve a useful signal-to-noise ratio.

### BRIEF DESCRIPTION OF THE DRAWINGS

FIG. 1 is a simplified block diagram of one embodiment of a photonic integrated circuit (PIC) die with an integrated pump laser, Raman laser, and four-wave mixing source.

FIG. 2 is a simplified block diagram of one embodiment of the Raman laser of FIG. 1.

FIG. 3 is a top-down view of one embodiment of a photonic integrated circuit (PIC) die with an integrated pump laser, Raman laser, and four-wave mixing source.

FIG. 4 is a plot showing spectral optical power as a function of wavelength for one embodiment of an integrated pump laser.

FIG. 5 is a plot showing spectral optical power as a function of wavelength for one embodiment of a Raman pump laser.

FIG. 6 is a plot showing spectral optical power as a function of wavelength for one embodiment of an integrated pump laser and a Raman laser on the same PIC die.

FIG. 7 is an isometric view of an integrated circuit component including a photonic integrated circuit (PIC) die and an electronic integrated circuit (EIC) die.

FIG. 8 is a cross-sectional view of one embodiment of the integrated circuit component of FIG. 7.

FIG. 9 is a top view of a wafer and dies that may be included in a microelectronic assembly, in accordance with any of the embodiments disclosed herein.

FIG. 10 is a cross-sectional side view of an integrated circuit device that may be included in a microelectronic assembly, in accordance with any of the embodiments disclosed herein.

FIGS. 11A-11D are perspective views of example planar, gate-all-around, and stacked gate-all-around transistors.

FIG. 12 is a cross-sectional side view of an integrated circuit device assembly that may include a microelectronic assembly, in accordance with any of the embodiments disclosed herein.

FIG. 13 is a block diagram of an example electrical device that may include a microelectronic assembly, in accordance with any of the embodiments disclosed herein.

### DETAILED DESCRIPTION

In various embodiments disclosed herein, a photonic integrated circuit (PIC) die includes a semiconductor laser, a Raman laser, and a spontaneous four-wave mixing (SFWM) source to generate pairs of entangled photons. The illustrative semiconductor laser has a relatively large gain bandwidth, and a corresponding large number of noise photons from amplified spontaneous emission are generated in the band of the entangled photons. Removing the amplified spontaneous emission typically requires off-chip filters, increasing cost and complexity. In the illustrative embodiment, the output of the semiconductor laser is used to pump the Raman laser. The Raman laser has a narrow gain bandwidth, generating fewer photons from amplified spontaneous emission in the band of the entangled photons. The output from the Raman laser is used to drive the SFWM source, generating entangled photons with a high signal-to-noise ratio.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

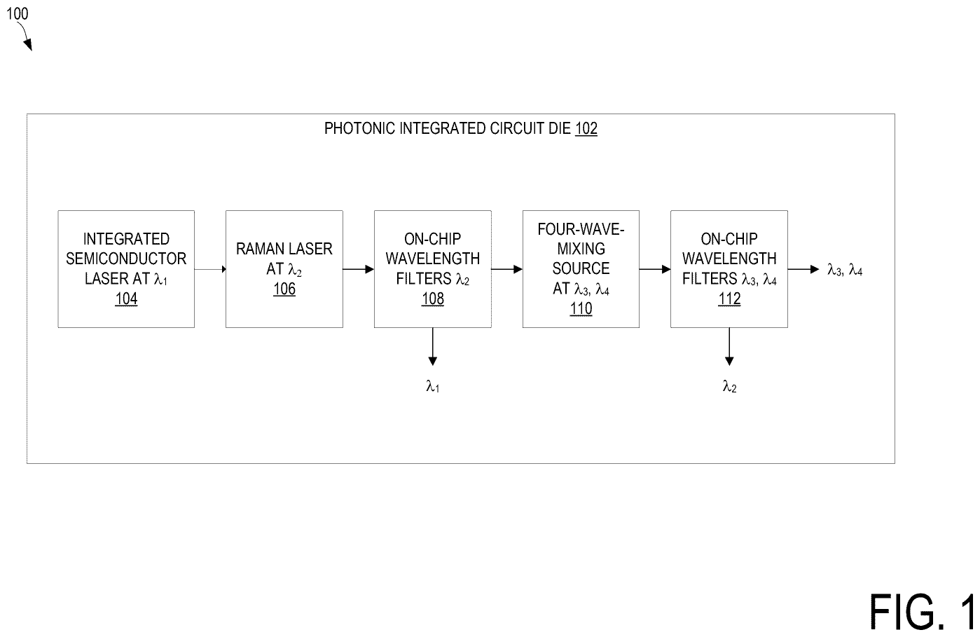

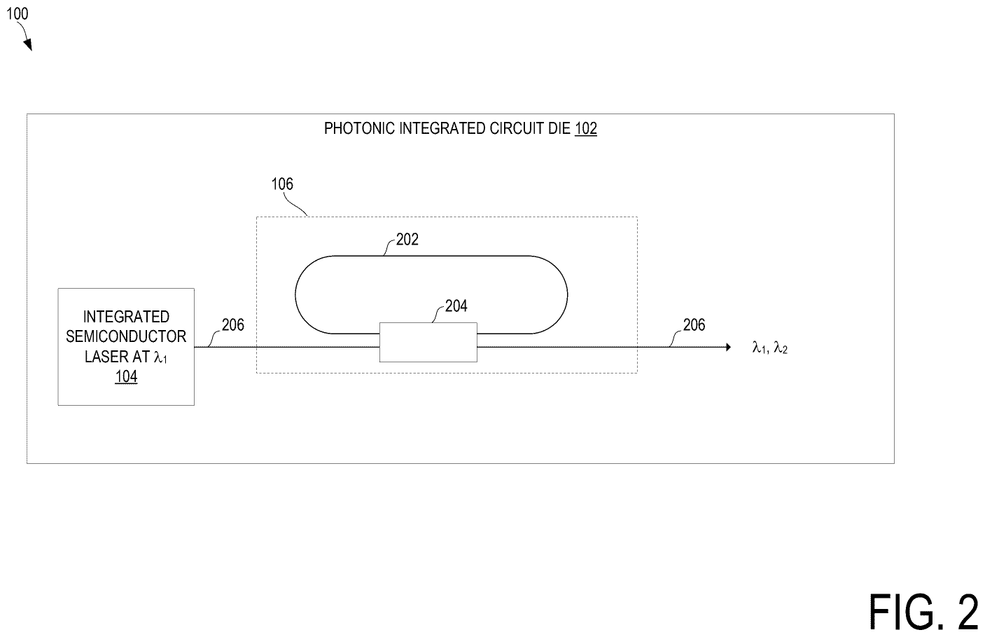

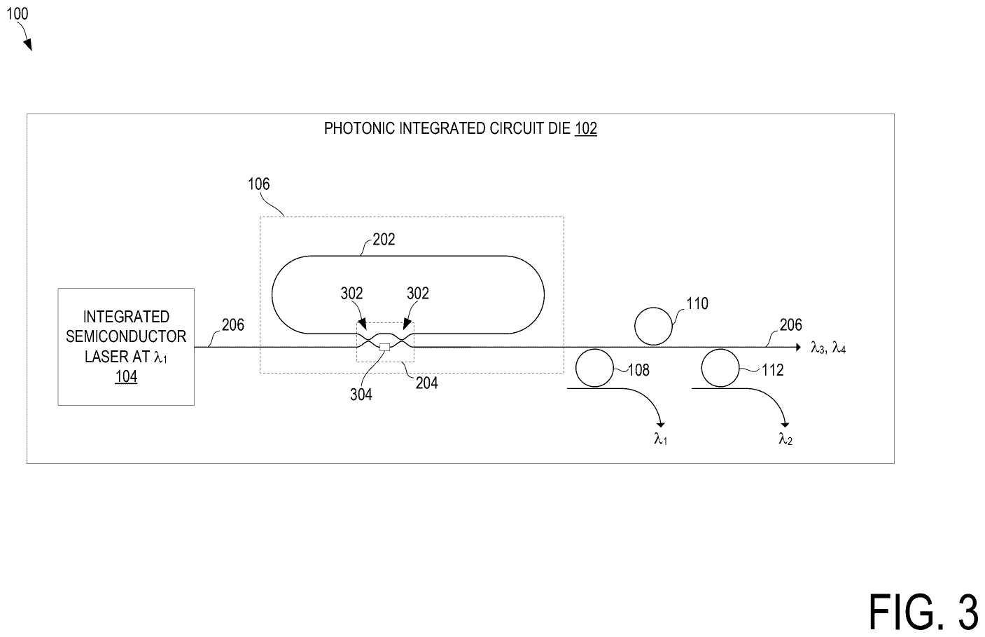

Referring now to FIG. 1, in one embodiment, a system 100 includes a PIC die 102. The PIC die 102 includes an integrated semiconductor laser 104, a Raman laser 106, a spontaneous four-wave mixing (SFWM) source 110, and filters 108, 112. In an illustrative embodiment, the integrated semiconductor laser 104 at wavelength λ₁ is used as a pump to drive the Raman laser 106 at wavelength λ₂, and the Raman laser 106 is used as a pump for the SFWM source 110 to generate pairs of photons at wavelengths λ₃ and λ₄. The filter 108 can be used to filter the light from the integrated semiconductor laser 104 at wavelength λ₁, and the filter 112 can be used to filter the light from the Raman laser 106 at wavelength λ₂. In some embodiments, filters 108, 112 on the die 102 may not be necessary, and the photons from the SFWM source 110 can be filtered from the semiconductor laser 104 and the Raman laser 106 off-chip. In an illustrative embodiment, the integrated semiconductor laser 104 is a hybrid III-V/silicon integrated photonics laser that is driven by an electric current. The III-V semiconductor forms an amplifier region for a laser, and silicon components are used to form the waveguide and the cavity, such as by using Bragg gratings or a ring resonator. The III-V semiconductor may be any suitable semiconductor, such as indium phosphide, gallium arsenide, etc. The III-V semiconductor may be integrated into the PIC die 102 in any suitable manner, such as using direct wafer bonding, epitaxial growth, flip-chip bonding, heterogeneous integration, and/or the like. The integrated semiconductor laser 104 may have any suitable wavelength, such as 1,200-1,600 nanometers. In an illustrative embodiment, the wavelength of the integrated semiconductor laser 104 is at O-band (about 1,260 to 1,360), or at about 1,305 nanometers. In some embodiments, the wavelength of the integrated semiconductor laser 104 may be longer, such as into the mid-infrared band, or from 1,600 nanometers to about 8 micrometers. The various other components of the system are described in more detail below in regard to FIGS. 2 and 3.

Referring now to FIG. 2, in one embodiment, the Raman laser 106 includes a waveguide resonator 202 and a coupler 204. In an illustrative embodiment, the resonator 202 may be resonant at both the wavelength of the semiconductor laser 104 and the wavelength of the Raman laser 106, allowing the light from the semiconductor laser 104 to build up in the resonator 202 and pump the Raman laser 106. Some of the light from the Raman laser 106 can be coupled out by the coupler 204 to the output of the Raman laser 106. The ring resonator 202 may have any suitable length, such as 0.1-20 centimeters. In an illustrative embodiment, the ring resonator 202 has a length of about 1.5 centimeters. To reduce loss in the ring resonator 202, in an illustrative embodiment, a p-i-n diode is integrated across the waveguide resonator 202, reducing the free carrier lifetime and density in the resonator 202, as well as providing a power signal. A p-i-n diode may also be integrated across part of the output bus waveguide 206 to read the output power. The resonator 202 may have any suitable shape, such as a ring, a racetrack, and/or the like.

In use, light from the integrated semiconductor laser 104 on a bus waveguide 206 is coupled to the resonator 202 by the coupler 204. Raman scattering of the light from the semiconductor laser 104 builds up in the waveguide resonator 202, achieving lasing and generating Raman laser light. In an illustrative embodiment with a silicon core waveguide, the Raman laser has a frequency that is shifted down from that of the semiconductor laser 104 by 15.6 terahertz. As the gain bandwidth for the Raman laser is fairly narrow, about 100 gigahertz, there is little to no amplified spontaneous emission outside of about 100 gigahertz from the linewidth of the Raman laser. Part of the light from the waveguide resonator 202 is coupled to the bus waveguide 206, which acts as an output for the Raman laser 106.

In an illustrative embodiment, the waveguide resonator 202 is a silicon waveguide with a silicon dioxide cladding. In general, the waveguide resonator 202, and other waveguides in the PIC die 102, may be any suitable type of waveguide, such as a silicon-on-insulator waveguide, a rib waveguide, a strip waveguide, a slot waveguide, a photonic crystal waveguide, etc. In an illustrative embodiment, the core of the waveguide resonator 202 is silicon, and the cladding of the waveguide resonator 202 is silicon dioxide. In other embodiments, any suitable materials may be used for the core and/or cladding, such as silicon, silicon nitride, silicon dioxide, aluminum oxide, aluminum nitride, amorphous silicon, hafnium dioxide, polymers, III-V semiconductors, chalcogenides, lithium niobate, gallium nitride, air, various dopants, etc. In general, the wavelength of the Raman laser depends on the core of the waveguide. Other optical components, such as optical fibers and/or optical interposers, may be connected to the PIC die 102 to provide optical signals into and out of the waveguides of the PIC die 102.

Referring now to FIG. 3, in an illustrative embodiment, possible embodiments for components such as the coupler 204, the filters 108, 112 and SFWM source 110 are shown. The coupler 204 may include two evanescent couplers 302 arranged in a Mach-Zehnder interferometer, with a heater 304 to control the phase of the Mach-Zehnder interferometer. The filters 108, 112 may be embodied as ring resonators resonant with light to be dropped from the bus waveguide 206.

In an illustrative embodiment, the SFWM source 110 is a ring resonator coupled to the bus waveguide 206. The ring resonator for the SFWM source 110 may have a diameter of, e.g., 5 to 10 microns. In an illustrative embodiment, the ring resonator is driven by the Raman laser at a wavelength of about 1406 nanometers, and the ring resonator has a free spectral range of about 6.5 nanometers (or about 1 terahertz). In such a configuration, the SFWM source 110 will generate pairs of photons at about 1395.5 nanometers and 1412.5 nanometers. As the Raman laser 106 has very low noise, even just a few nanometers away from the central frequency, the SFWM source 110 can have a high signal-to-noise ratio, such as a signal-to-noise ratio of over 100-1,000 or higher. In general, the SFWM source 110 may have any suitable free spectral range, such as 100 gigahertz or less to 10 terahertz or more. The signal-to-noise ratio for the SFWM source 110 is defined as the true coincidences of photon pairs detected divided by accidental coincidences of photon pairs detected. The various components of the PIC die 102, such as resonators 202, filters 108, 112, the SFWM source 110, etc., may be tuned using any suitable technique, such as heaters, p-i-n diodes, and/or the like, as appropriate.

In use, the pairs of photons from the SFWM source 110 may be used in any suitable manner. For example, the SFWM source 110 may be used for heralded single photon generation or an entangled photon pair generation. In an illustrative embodiment, the SFWM source 110 generates photon pairs that are time-frequency entangled. In some cases, multiple SFWM sources 110 may be combined, such as by spatially or temporally multiplexing several sources to create deterministic single photon sources, entangled photon pair sources, or sources of higher numbers of entangled photons. The output of one or more SFWM sources 110 may be used for any suitable application, such as quantum cryptography, quantum key distribution, quantum computing, quantum sensing, or other quantum information processing applications. The die 102 can be easily manufactured at scale and can act as a fundamental building block for quantum information systems, serving as a key resource of photonic quantum bits and helping link quantum systems together in a network. In some embodiments, the fully on-chip low-noise Raman laser 106 may be used directly as a light source, such as for sensing or LIDAR.

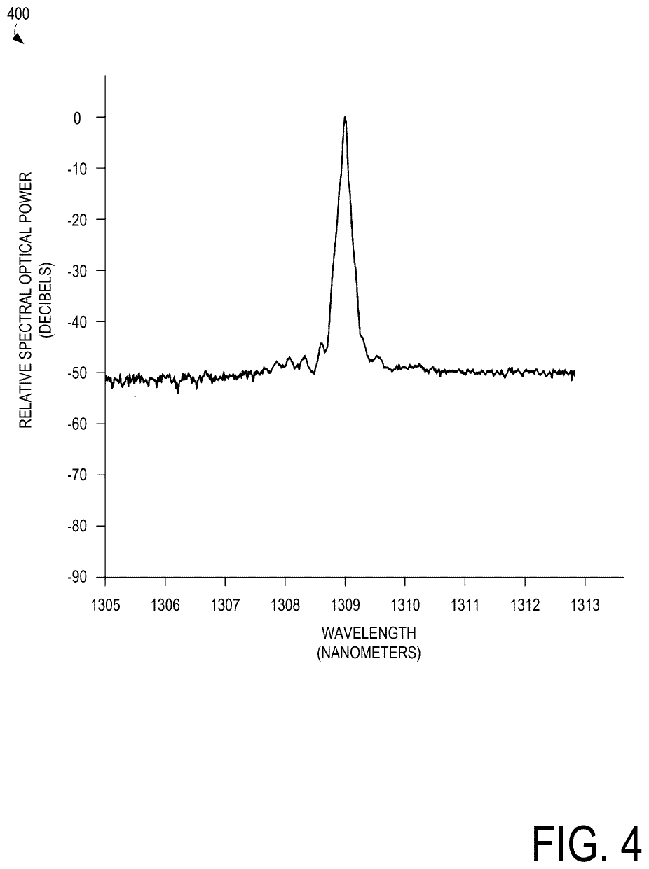

Referring now to FIG. 4, in one embodiment, a plot 400 shows the relative spectral optical power for one embodiment of a semiconductor laser 104. As can be seen from the plot 400, the background noise around the peak of the laser has a relative intensity of about −50 decibels.

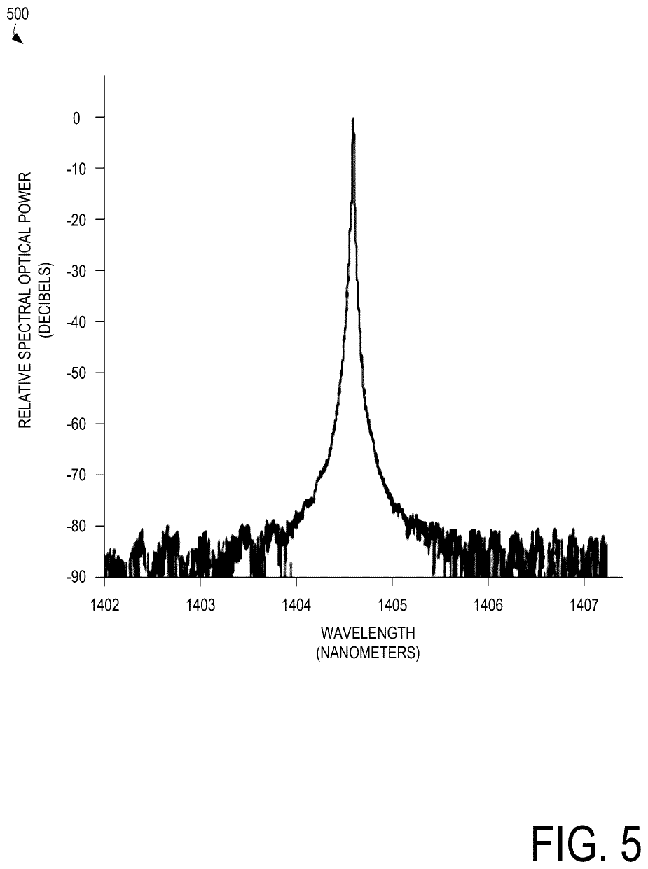

Referring now to FIG. 5, in one embodiment, a plot 500 shows the relative spectral optical power for one embodiment of a Raman laser 106. As can be seen from the plot 500, the background noise around the peak of the laser has a significantly smaller relative intensity of about −80 decibels, about three orders of magnitude lower than that of the semiconductor laser 104, limited by the noise floor of the measurement instrument.

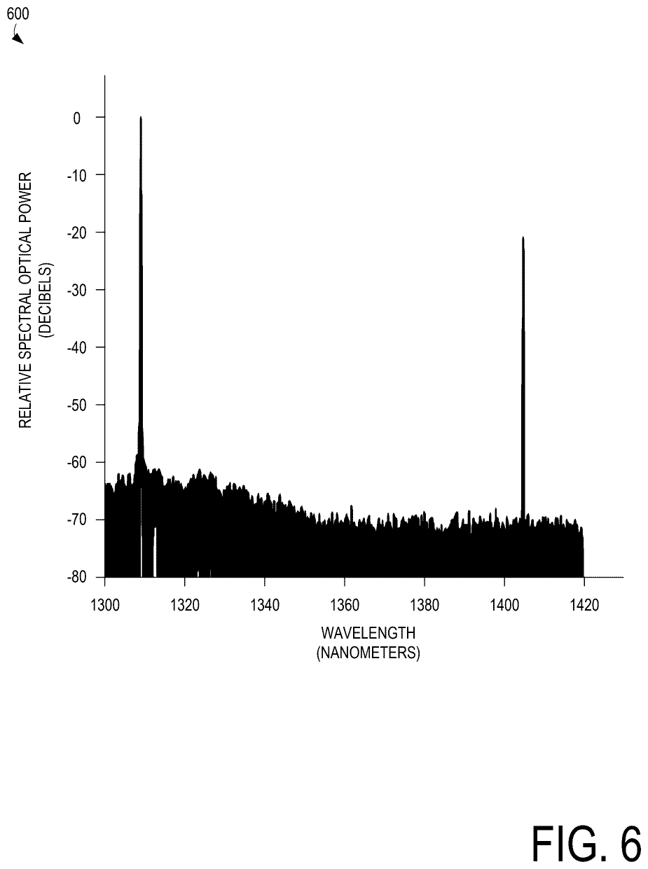

Referring now to FIG. 6, in one embodiment, a plot 600 shows the relative spectral optical power that was measured in one embodiment of a semiconductor laser 104 and a Raman laser 106 on the same die 102, where the Raman laser 106 is driven by the semiconductor laser 104. As can be seen from the plot 600, the background noise around the peak of the semiconductor laser 104 is clearly visible, but the background noise around the peak of the semiconductor laser 104 is significantly smaller, in the noise floor of the measurement.

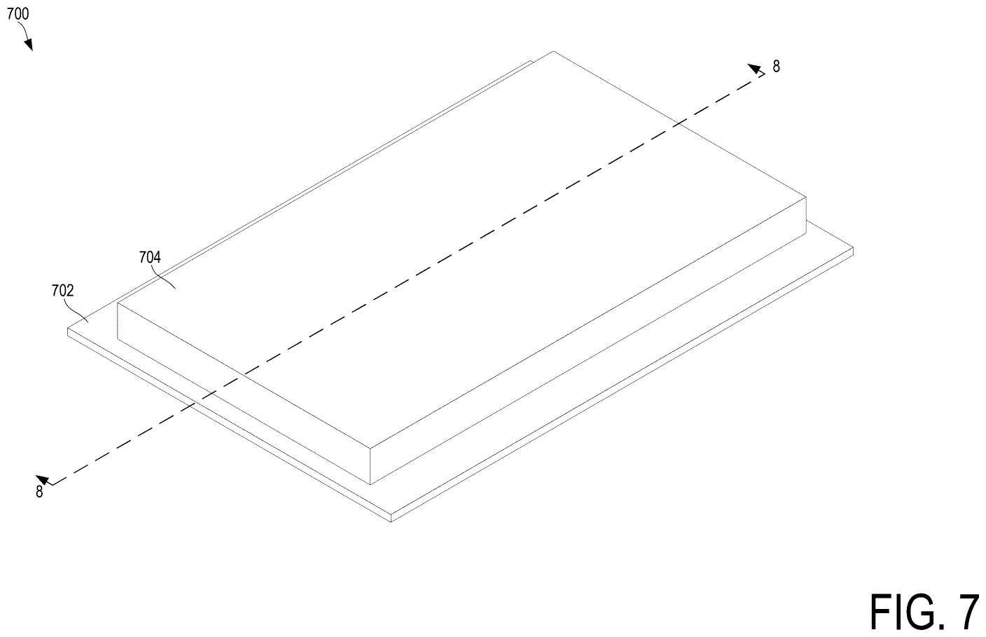

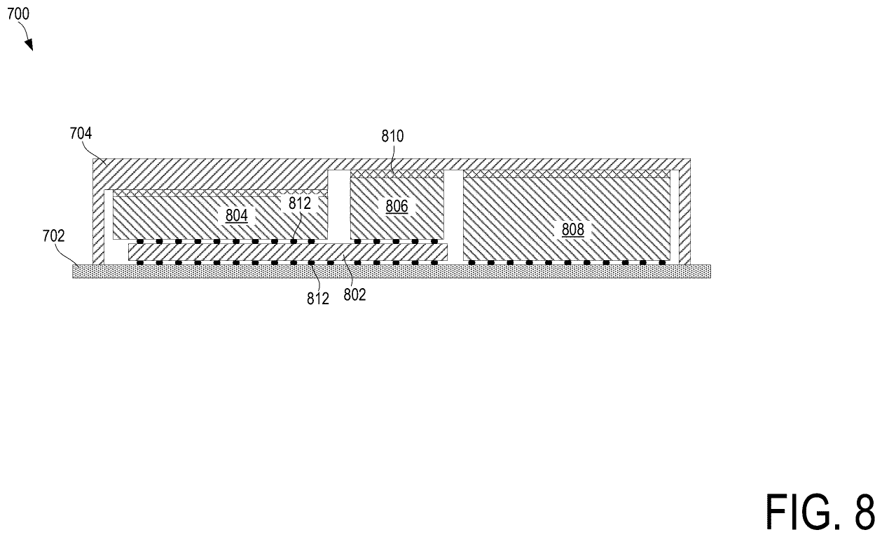

Referring now to FIGS. 7 and 8, in one embodiment, an integrated circuit component 700 includes a circuit board 702, an EIC die 802, a PIC die 804, and an integrated heat spreader 704. FIG. 7 shows a perspective view of the integrated circuit component 700, and FIG. 8 shows a cross-sectional view of one embodiment of the integrated circuit component 700. In an illustrative embodiment, the EIC die 802 is mounted on the circuit board 702, and the PIC die 804 is mounted on the EIC die 802. The integrated circuit component 700 may include other components, such as other EIC dies 806, 808. The other EIC dies 806, 808 may be, e.g., an XPU, a memory die or memory package, and/or the like. The PIC die 804 may be, e.g., any of the PIC dies 102 described above.

In an illustrative embodiment, the EIC die 802 and EIC die 808 are connected to the circuit board 702 with solder balls 812, and the EIC die 806 and PIC die 804 are connected to the EIC die 802 with solder balls 812. In other embodiments, the EIC die 802 and PIC die 804 may be connected using hybrid bonding. A thermal interface material (TIM) 810 is between the PIC die 804 and EIC dies 806, 808 and the integrated heat spreader 704.

The illustrative circuit board 702 may be made from ceramic, glass, and/or organic-based materials with fiberglass and resin, such as FR-4. The circuit board 702 may have any suitable length or width, such as 10-500 millimeters. The circuit board 702 may have any suitable thickness, such as 0.2-5 millimeters. The circuit board 702 may support additional components besides the components shown in FIGS. 7 and 8, such as additional photonic or electronic integrated circuit components, a memory device, additional circuit components, etc.

The PIC die 804 may be made of any suitable material, such as silicon. In the illustrative embodiment, waveguides may be silicon waveguides embedded in silicon dioxide cladding. The PIC die 804 may include any suitable number of waveguide inputs and/or outputs, such as 1-1,024. Other optical components, such as optical fibers and/or optical interposers, may be connected to the PIC die 804 to provide optical signals into and out of the waveguides of the PIC die 804. Components such as optical fibers may extend from the integrated circuit component 700, such as through the integrated heat spreader 704 and/or through the circuit board 702 (not shown in FIGS. 7 and 8).

The PIC die 804 is configured to generate, detect, and/or manipulate light. The PIC die 804 may include active or passive optical elements such as splitters, couplers, filters, optical amplifiers, lasers, photodetectors, modulators, etc.

The EIC die 802 may include any suitable electronic integrated circuit component, such as resistors, capacitors, inductors, transistors, etc. The EIC die 802 may include any suitable analog and/or digital circuitry, such as a processor, a memory, an application-specific integrated circuit (ASIC), a field-programmable gate array (FPGA), etc. In some embodiments, the integrated circuit component 700 may be embodied as or otherwise include a router, a switch, a network interface controller, and/or the like. In such embodiments, the EIC die 802 may include network interface controller circuitry to process, parse, route, etc., network packets sent and received by the integrated circuit component 700. Similarly, the EIC dies 806, 808 may be any suitable embodiment of the EIC die 802 described above in combination with any suitable embodiment of the EIC die 802.

The EIC dies 802, 806, 808 and/or the PIC die 804 may have any suitable length or width, such as 1-300 millimeters. The EIC dies 802, 806, 808 and/or the PIC die 804 may have any suitable thickness, such as 0.05-5 millimeters.

The integrated heat spreader 704 may be made of any suitable material with a high thermal conductivity, such as copper, aluminum, other metals, metal alloys, coated metals, combinations of metals, etc. In an illustrative embodiment, the integrated heat spreader 704 is nickel-plated copper. In use, a heat sink with fins or another heat transfer component, such as a liquid-cooled cold plate, may be mated with the integrated heat spreader 704 to remove heat.

The EIC die 802 and/or the PIC die 804 may include any suitable number of solder balls 812, such as 1-10,000. The solder balls 812 may be arranged in any suitable pattern, such as a two-dimensional grid. The solder balls 812 may have any suitable size, such as 10-1,000 micrometers, and any suitable pitch, such as 25 to 1,500 micrometers. The solder balls 812 may be made of or otherwise include any suitable type of solder, such as tin/lead solder, a lead-free solder, a high-temperature solder, etc. The solder balls 812 may include by weight, e.g., 0-50% lead, 0-97% tin, 0-50% silver, 0-5% copper, 0-85% gold, or any suitable combination thereof. The melting point of the solder balls 812 may be, e.g., 180-400° C., depending on the particular application. The solder balls 812 may connect to an active component on the PIC die 804, such as a laser, an amplifier, a detector, a modulator, a switch, etc.

In an illustrative embodiment, the PIC die 804 includes a substrate layer and a stack of one or more dielectric layers adjacent the substrate layer. In an illustrative embodiment, waveguides are defined in some or all of the dielectric layers. The PIC die 804 may also include various other components, such as lasers, amplifiers, detectors, modulators, switches, filters, couplers, etc. The various waveguides of the PIC die 804 may be routed in three dimensions to various other components on the PIC die 804. Light may be coupled onto and off of the PIC die 804 in any suitable manner, such as direct coupling to other dies, butt-coupling of fibers or waveguides, grating coupling, vertical couplers, lenses, mirrors, etc.

In an illustrative embodiment, the substrate layer is silicon. In other embodiments, other suitable substrates may be used. The substrate layer may have any suitable thickness, such as 40-5,000 micrometers. In an illustrative embodiment, the dielectric layers are silicon dioxide and the waveguides are silicon. In other embodiments, other suitable materials may be used for any of the dielectric layers and waveguides, such as silicon, silicon nitride, silicon dioxide, aluminum oxide, aluminum nitride, amorphous silicon, hafnium dioxide, polymers, III-V semiconductors, chalcogenides, lithium niobate, gallium nitride, air, various dopants, etc. Of course, it should be appreciated that the waveguides will be structured to guide light, such as by being a higher index than the adjacent dielectric cladding. In general, the core and/or cladding may have any suitable indices of refraction, such as 1.4-4.

In an illustrative embodiment, the dielectric layers are about 2 micrometers thick. In other embodiments, the dielectric layers may have any suitable thickness, such as 0.5-20 micrometers. The waveguides may have any suitable width and/or thickness, such as 0.2-20 micrometers. In an illustrative embodiment, the height and width of the waveguides may be selected to support single-mode operation in the waveguides, depending on the wavelength, index of refraction of the waveguides, index of refraction of the cladding, polarization, etc. In other embodiments, the height and width of the waveguides may be selected to support multi-mode operation in the waveguides. For example, in some embodiments, the PIC die 804 may use spatial mode-division multiplexing to increase the bandwidth carried per waveguide.

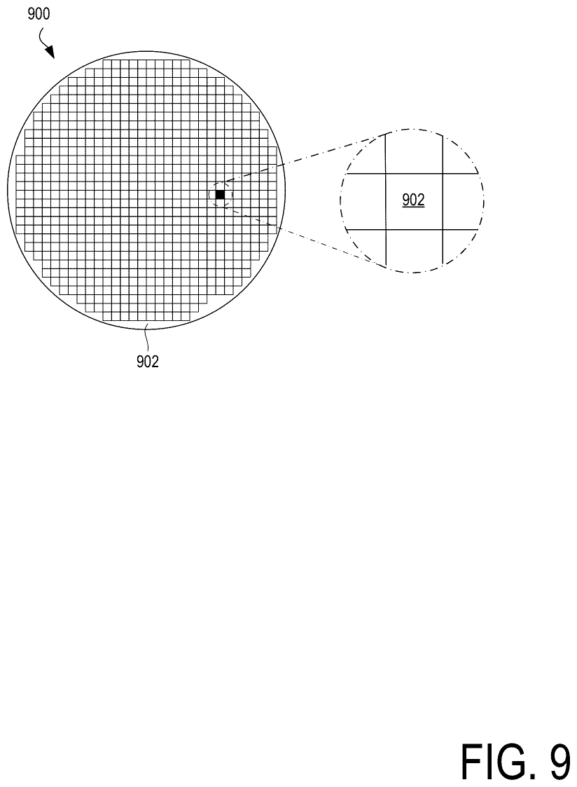

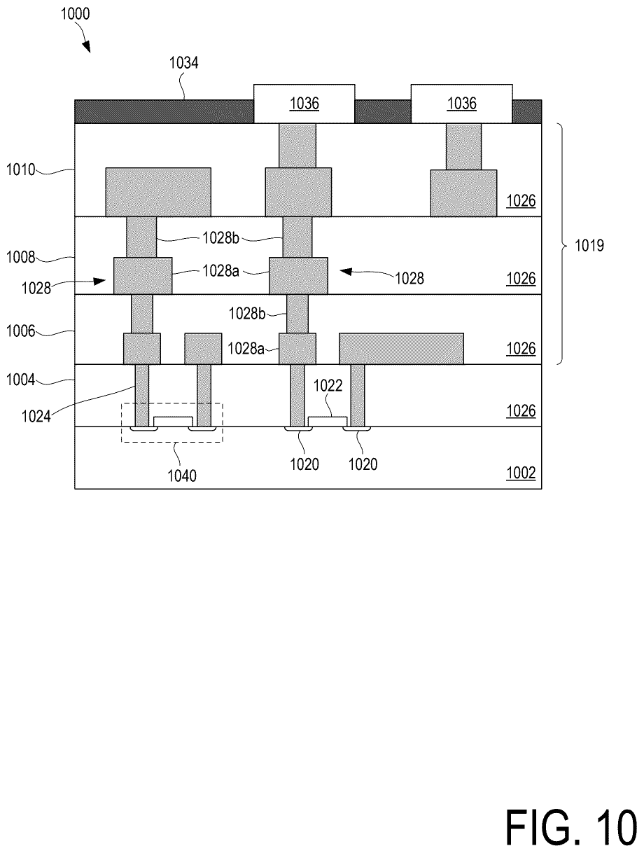

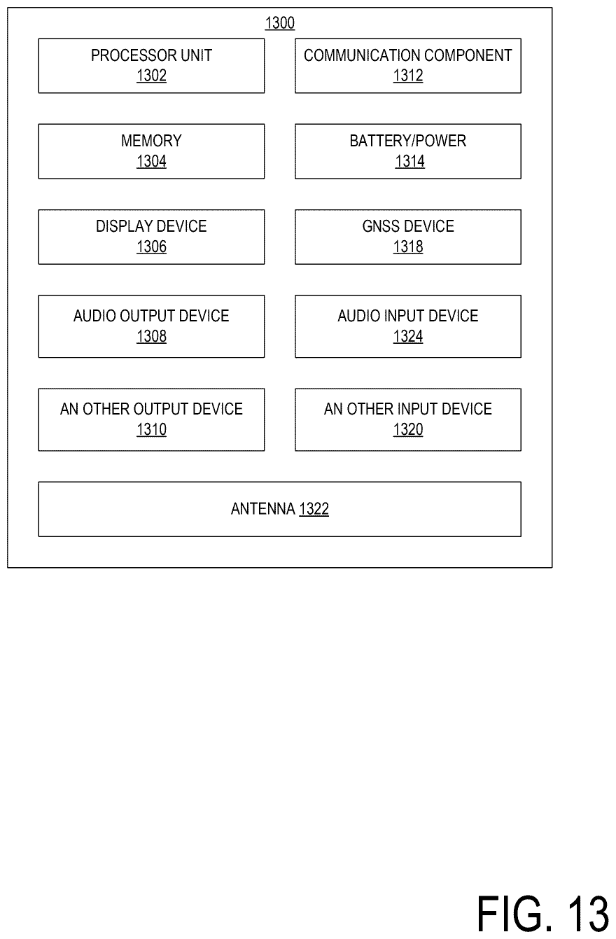

FIG. 9 is a top view of a wafer 900 and dies 902 that may be included in any of the integrated circuit components 700 disclosed herein (e.g., as any suitable ones of the dies 102). The wafer 900 may be composed of semiconductor material and may include one or more dies 902 having integrated circuit structures formed on a surface of the wafer 900. The individual dies 902 may be a repeating unit of an integrated circuit product that includes any suitable integrated circuit. After the fabrication of the semiconductor product is complete, the wafer 900 may undergo a singulation process in which the dies 902 are separated from one another to provide discrete “chips” of the integrated circuit product. The die 902 may be any of the dies 102 disclosed herein. The die 902 may include one or more transistors (e.g., some of the transistors 1040 of FIG. 10, discussed below), supporting circuitry to route electrical signals to the transistors, passive components (e.g., signal traces, resistors, capacitors, or inductors), and/or any other integrated circuit components. In some embodiments, the wafer 900 or the die 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 902. For example, a memory array formed by multiple memory devices may be formed on a same die 902 as a processor unit (e.g., the processor unit 1302 of FIG. 13) or other logic that is configured to store information in the memory devices or execute instructions stored in the memory array. Various ones of the integrated circuit components 700 disclosed herein may be manufactured using a die-to-wafer assembly technique in which some dies 102 are attached to a wafer 900 that include others of the dies 102, and the wafer 900 is subsequently singulated.

FIG. 10 is a cross-sectional side view of an integrated circuit device 1000 that may be included in any of the integrated circuit components 700 disclosed herein (e.g., in any of the dies 102). One or more of the integrated circuit devices 1000 may be included in one or more dies 902 (FIG. 9). The integrated circuit device 1000 may be formed on a die substrate 1002 (e.g., the wafer 900 of FIG. 9) and may be included in a die (e.g., the die 902 of FIG. 9). The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some embodiments, the die substrate 1002 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an integrated circuit device 1000 may be used. The die substrate 1002 may be part of a singulated die (e.g., the dies 902 of FIG. 9) or a wafer (e.g., the wafer 900 of FIG. 9).

The integrated circuit device 1000 may include one or more device layers 1004 disposed on the die substrate 1002. The device layer 1004 may include features of one or more transistors 1040 (e.g., metal oxide semiconductor field-effect transistors (MOSFETs)) formed on the die substrate 1002. The transistors 1040 may include, for example, one or more source and/or drain (S/D) regions 1020, a gate 1022 to control current flow between the S/D regions 1020, and one or more S/D contacts 1024 to route electrical signals to/from the S/D regions 1020. The transistors 1040 may include additional features not depicted for the sake of clarity, such as device isolation regions, gate contacts, and the like. The transistors 1040 are not limited to the type and configuration depicted in FIG. 10 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

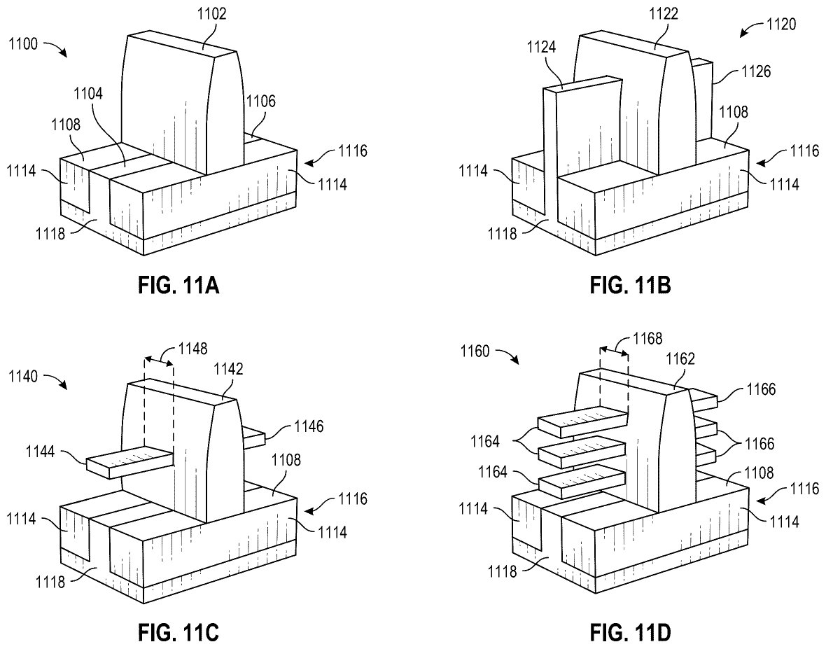

FIGS. 11A-11D are simplified perspective views of example planar, FinFET, gate-all-around, and stacked gate-all-around transistors. The transistors illustrated in FIGS. 11A-11D are formed on a substrate 1116 having a surface 1108. Isolation regions 1114 separate the source and drain regions of the transistors from other transistors and from a bulk region 1118 of the substrate 1116.

FIG. 11A is a perspective view of an example planar transistor 1100 comprising a gate 1102 that controls current flow between a source region 1104 and a drain region 1106. The transistor 1100 is planar in that the source region 1104 and the drain region 1106 are planar with respect to the substrate surface 1108.

FIG. 11B is a perspective view of an example FinFET transistor 1120 comprising a gate 1122 that controls current flow between a source region 1124 and a drain region 1126. The transistor 1120 is non-planar in that the source region 1124 and the drain region 1126 comprise “fins” that extend upwards from the substrate surface 1128. As the gate 1122 encompasses three sides of the semiconductor fin that extends from the source region 1124 to the drain region 1126, the transistor 1120 can be considered a tri-gate transistor. FIG. 11B illustrates one S/D fin extending through the gate 1122, but multiple S/D fins can extend through the gate of a FinFET transistor.

FIG. 11C is a perspective view of a gate-all-around (GAA) transistor 1140 comprising a gate 1142 that controls current flow between a source region 1144 and a drain region 1146. The transistor 1140 is non-planar in that the source region 1144 and the drain region 1146 are elevated from the substrate surface 1128.

FIG. 11D is a perspective view of a GAA transistor 1160 comprising a gate 1162 that controls current flow between multiple elevated source regions 1164 and multiple elevated drain regions 1166. The transistor 1160 is a stacked GAA transistor as the gate controls the flow of current between multiple elevated S/D regions stacked on top of each other. The transistors 1140 and 1160 are considered gate-all-around transistors as the gates encompass all sides of the semiconductor portions that extends from the source regions to the drain regions. The transistors 1140 and 1160 can alternatively be referred to as nanowire, nanosheet, or nanoribbon transistors depending on the width (e.g., widths 1148 and 1168 of transistors 1140 and 1160, respectively) of the semiconductor portions extending through the gate.

Returning to FIG. 10, a transistor 1040 may include a gate 1022 formed of at least two layers, a gate dielectric and a gate electrode. The gate dielectric may include one layer or a stack of layers. The one or more layers may include, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon dioxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1040 along the source-channel-drain direction, the gate electrode may consist of a U-shaped structure that includes a bottom portion substantially parallel to the surface of the die substrate 1002 and two sidewall portions that are substantially perpendicular to the top surface of the die substrate 1002. In other embodiments, at least one of the metal layers that form the gate electrode may simply be a planar layer that is substantially parallel to the top surface of the die substrate 1002 and does not include sidewall portions substantially perpendicular to the top surface of the die substrate 1002. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon dioxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of individual transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1020 may be formed using one or more alternate semiconductor materials such as germanium or a group III-V material or alloy. In further embodiments, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the integrated circuit device 1000.

The interconnect structures 1028 may be arranged within the interconnect layers 1006-1010 to route electrical signals according to a wide variety of designs; in particular, the arrangement is not limited to the particular configuration of interconnect structures 1028 depicted in FIG. 10. Although a particular number of interconnect layers 1006-1010 is depicted in FIG. 10, embodiments of the present disclosure include integrated circuit devices having more or fewer interconnect layers than depicted.

In some embodiments, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page and/or in a direction across the page. The vias 1028b may be arranged to route electrical signals in a direction of a plane that is substantially perpendicular to the surface of the die substrate 1002 upon which the device layer 1004 is formed. In some embodiments, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some embodiments, dielectric material 1026 disposed between the interconnect structures 1028 in different ones of the interconnect layers 1006-1010 may have different compositions; in other embodiments, the composition of the dielectric material 1026 between different interconnect layers 1006-1010 may be the same. The device layer 1004 may include a dielectric material 1026 disposed between the transistors 1040 and a bottom layer of the metallization stack as well. The dielectric material 1026 included in the device layer 1004 may have a different composition than the dielectric material 1026 included in the interconnect layers 1006-1010; in other embodiments, the composition of the dielectric material 1026 in the device layer 1004 may be the same as a dielectric material 1026 included in any one of the interconnect layers 1006-1010.

A first interconnect layer 1006 (referred to as Metal 1 or “M1”) may be formed directly on the device layer 1004. In some embodiments, the first interconnect layer 1006 may include lines 1028a and/or vias 1028b, as shown. The lines 1028a of the first interconnect layer 1006 may be coupled with contacts (e.g., the S/D contacts 1024) of the device layer 1004. The vias 1028b of the first interconnect layer 1006 may be coupled with the lines 1028a of a second interconnect layer 1008.

The second interconnect layer 1008 (referred to as Metal 2 or “M2”) may be formed directly on the first interconnect layer 1006. In some embodiments, the second interconnect layer 1008 may include via 1028b to couple the lines 1028 of the second interconnect layer 1008 with the lines 1028a of a third interconnect layer 1010. Although the lines 1028a and the vias 1028b are structurally delineated with a line within individual interconnect layers for the sake of clarity, the lines 1028a and the vias 1028b may be structurally and/or materially contiguous (e.g., simultaneously filled during a dual-damascene process) in some embodiments.

The third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 or the first interconnect layer 1006. In some embodiments, the interconnect layers that are “higher up” in the metallization stack 1019 in the integrated circuit device 1000 (i.e., farther away from the device layer 1004) may be thicker that the interconnect layers that are lower in the metallization stack 1019, with lines 1028a and vias 1028b in the higher interconnect layers being thicker than those in the lower interconnect layers.

The integrated circuit device 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to external devices. For example, solder bonds may be formed on the one or more conductive contacts 1036 to mechanically and/or electrically couple an integrated circuit die including the integrated circuit device 1000 with another component (e.g., a printed circuit board). The integrated circuit device 1000 may include additional or alternate structures to route the electrical signals from the interconnect layers 1006-1010; for example, the conductive contacts 1036 may include other analogous features (e.g., posts) that route the electrical signals to external components.

In some embodiments in which the integrated circuit device 1000 is a double-sided die, the integrated circuit device 1000 may include another metallization stack (not shown) on the opposite side of the device layer(s) 1004. This metallization stack may include multiple interconnect layers as discussed above with reference to the interconnect layers 1006-1010, to provide conductive pathways (e.g., including conductive lines and vias) between the device layer(s) 1004 and additional conductive contacts (not shown) on the opposite side of the integrated circuit device 1000 from the conductive contacts 1036.

In other embodiments in which the integrated circuit device 1000 is a double-sided die, the integrated circuit device 1000 may include one or more through silicon vias (TSVs) through the die substrate 1002; these TSVs may make contact with the device layer(s) 1004, and may provide conductive pathways between the device layer(s) 1004 and additional conductive contacts (not shown) on the opposite side of the integrated circuit device 1000 from the conductive contacts 1036. In some embodiments, TSVs extending through the substrate can be used for routing power and ground signals from conductive contacts on the opposite side of the integrated circuit device 1000 from the conductive contacts 1036 to the transistors 1040 and any other components integrated into the die 1000, and the metallization stack 1019 can be used to route I/O signals from the conductive contacts 1036 to transistors 1040 and any other components integrated into the die 1000.

Multiple integrated circuit devices 1000 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

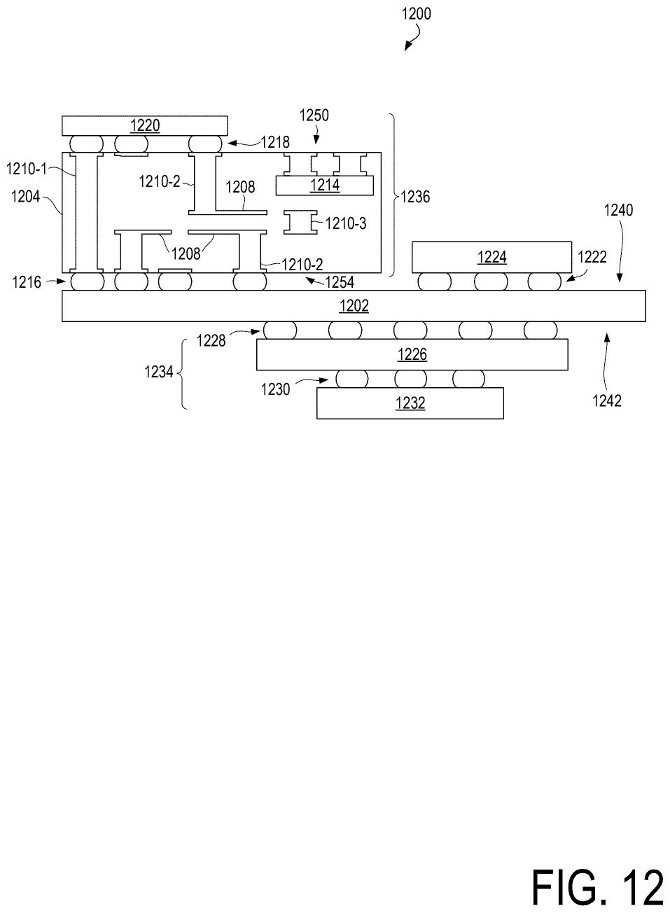

FIG. 12 is a cross-sectional side view of an integrated circuit device assembly 1200 that may include any of the integrated circuit components 700 disclosed herein. In some embodiments, the integrated circuit device assembly 1200 may be an integrated circuit component 700. The integrated circuit device assembly 1200 includes a number of components disposed on a circuit board 1202 (which may be a motherboard, system board, mainboard, etc.). The integrated circuit device assembly 1200 includes components disposed on a first face 1240 of the circuit board 1202 and an opposing second face 1242 of the circuit board 1202; generally, components may be disposed on one or both faces 1240 and 1242. Any of the integrated circuit components discussed below with reference to the integrated circuit device assembly 1200 may take the form of any suitable ones of the embodiments of the integrated circuit components 700 disclosed herein.

In some embodiments, the circuit board 1202 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1202. In other embodiments, the circuit board 1202 may be a non-PCB substrate. In some embodiments the circuit board 1202 may be, for example, the circuit board 702. The integrated circuit device assembly 1200 illustrated in FIG. 12 includes a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 12), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1216 may serve as the coupling components illustrated or described for any of the substrate assembly or substrate assembly components described herein, as appropriate.

The package-on-interposer structure 1236 may include an integrated circuit component 1220 coupled to an interposer 1204 by coupling components 1218. The coupling components 1218 may take any suitable form for the application, such as the forms discussed above with reference to the coupling components 1216. Although a single integrated circuit component 1220 is shown in FIG. 12, multiple integrated circuit components may be coupled to the interposer 1204; indeed, additional interposers may be coupled to the interposer 1204. The interposer 1204 may provide an intervening substrate used to bridge the circuit board 1202 and the integrated circuit component 1220.

The integrated circuit component 1220 may be a packaged or unpacked integrated circuit product that includes one or more integrated circuit dies (e.g., the die 902 of FIG. 9, the integrated circuit device 1000 of FIG. 10) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1220, a single monolithic integrated circuit die comprises solder bumps attached to contacts on the die. The solder bumps allow the die to be directly attached to the interposer 1204. The integrated circuit component 1220 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1220 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1220 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1220 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1204 may spread connections to a wider pitch or reroute a connection to a different connection. For example, the interposer 1204 may couple the integrated circuit component 1220 to a set of ball grid array (BGA) conductive contacts of the coupling components 1216 for coupling to the circuit board 1202. In the embodiment illustrated in FIG. 12, the integrated circuit component 1220 and the circuit board 1202 are attached to opposing sides of the interposer 1204; in other embodiments, the integrated circuit component 1220 and the circuit board 1202 may be attached to a same side of the interposer 1204. In some embodiments, three or more components may be interconnected by way of the interposer 1204.

In some embodiments, the interposer 1204 may be formed as a PCB, including multiple metal layers separated from one another by layers of dielectric material and interconnected by electrically conductive vias. In some embodiments, the interposer 1204 may be formed of an epoxy resin, a fiberglass-reinforced epoxy resin, an epoxy resin with inorganic fillers, a ceramic material, or a polymer material such as polyimide. In some embodiments, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias 1210, including but not limited to through hole vias 1210-1 (that extend from a first face 1250 of the interposer 1204 to a second face 1254 of the interposer 1204), blind vias 1210-2 (that extend from the first or second faces 1250 or 1254 of the interposer 1204 to an internal metal layer), and buried vias 1210-3 (that connect internal metal layers).

In some embodiments, the interposer 1204 can comprise a silicon interposer. Through silicon vias (TSV) extending through the silicon interposer can connect connections on a first face of a silicon interposer to an opposing second face of the silicon interposer. In some embodiments, an interposer 1204 comprising a silicon interposer can further comprise one or more routing layers to route connections on a first face of the interposer 1204 to an opposing second face of the interposer 1204.

The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art.

The integrated circuit device assembly 1200 may include an integrated circuit component 1224 coupled to the first face 1240 of the circuit board 1202 by coupling components 1222. The coupling components 1222 may take the form of any of the embodiments discussed above with reference to the coupling components 1216, and the integrated circuit component 1224 may take the form of any of the embodiments discussed above with reference to the integrated circuit component 1220.

The integrated circuit device assembly 1200 illustrated in FIG. 12 includes a package-on-package structure 1234 coupled to the second face 1242 of the circuit board 1202 by coupling components 1228. The package-on-package structure 1234 may include an integrated circuit component 1226 and an integrated circuit component 1232 coupled together by coupling components 1230 such that the integrated circuit component 1226 is disposed between the circuit board 1202 and the integrated circuit component 1232. The coupling components 1228 and 1230 may take the form of any of the embodiments of the coupling components 1216 discussed above, and the integrated circuit components 1226 and 1232 may take the form of any of the embodiments of the integrated circuit component 1220 discussed above. The package-on-package structure 1234 may be configured in accordance with any of the package-on-package structures known in the art.

FIG. 13 is a block diagram of an example electrical device 1300 that may include one or more of the integrated circuit components 700 disclosed herein. For example, any suitable ones of the components of the electrical device 1300 may include one or more of the integrated circuit device assemblies 1200, integrated circuit components 1220, integrated circuit devices 1000, or integrated circuit dies 902 disclosed herein, and may be arranged in any of the integrated circuit components 700 disclosed herein. A number of components are illustrated in FIG. 13 as included in the electrical device 1300, but any one or more of these components may be omitted or duplicated, as suitable for the application. In some embodiments, some or all of the components included in the electrical device 1300 may be attached to one or more motherboards mainboards, or system boards. In some embodiments, one or more of these components are fabricated onto a single system-on-a-chip (SoC) die.

Additionally, in various embodiments, the electrical device 1300 may not include one or more of the components illustrated in FIG. 13, but the electrical device 1300 may include interface circuitry for coupling to the one or more components. For example, the electrical device 1300 may not include a display device 1306, but may include display device interface circuitry (e.g., a connector and driver circuitry) to which a display device 1306 may be coupled. In another set of examples, the electrical device 1300 may not include an audio input device 1324 or an audio output device 1308, but may include audio input or output device interface circuitry (e.g., connectors and supporting circuitry) to which an audio input device 1324 or audio output device 1308 may be coupled.

The electrical device 1300 may include one or more processor units 1302 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1302 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1300 may include a memory 1304, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1304 may include memory that is located on the same integrated circuit die as the processor unit 1302. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1300 can comprise one or more processor units 1302 that are heterogeneous or asymmetric to another processor unit 1302 in the electrical device 1300. There can be a variety of differences between the processing units 1302 in a system in terms of a spectrum of metrics of merit including architectural, microarchitectural, thermal, power consumption characteristics, and the like. These differences can effectively manifest themselves as asymmetry and heterogeneity among the processor units 1302 in the electrical device 1300.

In some embodiments, the electrical device 1300 may include a communication component 1312 (e.g., one or more communication components). For example, the communication component 1312 can manage wireless communications for the transfer of data to and from the electrical device 1300. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1312 may operate in accordance with other wireless protocols in other embodiments. The electrical device 1300 may include an antenna 1322 to facilitate wireless communications and/or to receive other wireless communications (such as AM or FM radio transmissions).

In some embodiments, the communication component 1312 may manage wired communications, such as electrical, optical, or any other suitable communication protocols (e.g., IEEE 802.3 Ethernet standards). As noted above, the communication component 1312 may include multiple communication components. For instance, a first communication component 1312 may be dedicated to shorter-range wireless communications such as Wi-Fi or Bluetooth, and a second communication component 1312 may be dedicated to longer-range wireless communications such as global positioning system (GPS), EDGE, GPRS, CDMA, WiMAX, LTE, EV-DO, or others. In some embodiments, a first communication component 1312 may be dedicated to wireless communications, and a second communication component 1312 may be dedicated to wired communications.

The electrical device 1300 may include battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display device 1306 (or corresponding interface circuitry, as discussed above). The display device 1306 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any embedded or wired or wirelessly connected external device that generates an audible indicator, such as speakers, headsets, or earbuds.

The electrical device 1300 may include an audio input device 1324 (or corresponding interface circuitry, as discussed above). The audio input device 1324 may include any embedded or wired or wirelessly connected device that generates a signal representative of a sound, such as microphones, microphone arrays, or digital instruments (e.g., instruments having a musical instrument digital interface (MIDI) output). The electrical device 1300 may include a Global Navigation Satellite System (GNSS) device 1318 (or corresponding interface circuitry, as discussed above), such as a Global Positioning System (GPS) device. The GNSS device 1318 may be in communication with a satellite-based system and may determine a geolocation of the electrical device 1300 based on information received from one or more GNSS satellites, as known in the art.

The electrical device 1300 may include an other output device 1310 (or corresponding interface circuitry, as discussed above). Examples of the other output device 1310 may include an audio codec, a video codec, a printer, a wired or wireless transmitter for providing information to other devices, or an additional storage device.

The electrical device 1300 may include an other input device 1320 (or corresponding interface circuitry, as discussed above). Examples of the other input device 1320 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1300 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1300 may be any other electronic device that processes data. In some embodiments, the electrical device 1300 may comprise multiple discrete physical components. Given the range of devices that the electrical device 1300 can be manifested as in various embodiments, in some embodiments, the electrical device 1300 can be referred to as a computing device or a computing system.

### EXAMPLES

Illustrative examples of the technologies disclosed herein are provided below. An embodiment of the technologies may include any one or more, and any combination of, the examples described below.
Example 1 includes a photonic integrated circuit (PIC) die comprising a semiconductor laser; a Raman laser, wherein an output of the semiconductor laser is coupled to the Raman laser, wherein the semiconductor laser is to pump the Raman laser; and a resonator, wherein an output of the Raman laser is coupled to the resonator.
Example 2 includes the subject matter of Example 1, and wherein, in use, the Raman laser is to pump the resonator to create entangled photon pairs using spontaneous four-wave mixing.
Example 3 includes the subject matter of any of Examples 1 and 2, and wherein the resonator acts as a spontaneous four-wave mixing (SFWM) source, wherein the SFWM has a signal-to-noise ratio of at least 1,000.
Example 4 includes the subject matter of any of Examples 1-3, and wherein the Raman laser has a gain bandwidth less than 200 gigahertz.
Example 5 includes the subject matter of any of Examples 1-4, and wherein the semiconductor laser is a hybrid III-V/silicon semiconductor laser.

Example 6 includes the subject matter of any of Examples 1-5, and wherein the Raman laser has a relative optical power of less than 70 dB at one nanometer away from a peak of the Raman laser.
Example 7 includes the subject matter of any of Examples 1-6, and wherein the resonator has a free spectral range between 200 gigahertz and 2,000 gigahertz.
Example 8 includes an integrated circuit component comprising the PIC die of any of Examples 1-7, further comprising an electronic integrated circuit (EIC) die mated with the PIC die; a plurality of solder balls positioned between the EIC die and the PIC die, wherein individual solder balls of the plurality of solder balls are adjacent individual contact pads of the plurality of contact pads of the PIC die; and a circuit board mated to the EIC die.
Example 9 includes a quantum cryptography system comprising the PIC die of any of Examples 1-8.
Example 10 includes the subject matter of Example 9, and further including a filter to remove light from the semiconductor laser from a bus waveguide after the Raman laser.
Example 11 includes the subject matter of any of Examples 9 and 10, and wherein there is no filter to remove light from the semiconductor laser from a bus waveguide after the Raman laser and before the resonator.
Example 12 includes a LIDAR system comprising the PIC die of any of Examples 1-11.
Example 13 includes a photonic integrated circuit (PIC) die comprising a first silicon waveguide forming a first resonator, the first silicon waveguide coupled to an amplifier region, wherein the first resonator is resonant at a first frequency; a second silicon waveguide forming a second resonator, wherein the second resonator is resonant at the first frequency and at a second frequency, wherein the second frequency is a Raman shift away from the first frequency; and one or more waveguides to couple light between the first resonator and the second resonator.
Example 14 includes the subject matter of Example 13, and further including a third silicon waveguide forming a third resonator, wherein the third resonator has a free spectral range between 200 gigahertz and 2,000 gigahertz, wherein the third resonator is resonant with the second frequency, wherein the one or more waveguides are to couple light between the second resonator and the third resonator.
Example 15 includes the subject matter of any of Examples 13 and 14, and wherein the amplifier region comprises a III-V semiconductor.
Example 16 includes the subject matter of any of Examples 13-15, and further including a third resonator, wherein, in use, the second resonator is to act as a Raman laser to pump the third resonator to create entangled photon pairs using spontaneous four-wave mixing.
Example 17 includes the subject matter of any of Examples 13-16, and wherein the resonator acts as a spontaneous four-wave mixing (SFWM) source, wherein the SFWM has a signal-to-noise ratio of at least 1,000.
Example 18 includes the subject matter of any of Examples 13-17, and wherein the Raman laser has a gain bandwidth less than 200 gigahertz.
Example 19 includes the subject matter of any of Examples 13-18, and wherein the Raman laser has a relative optical power of less than 70 dB at one nanometer away from a peak of the Raman laser.
Example 20 includes the subject matter of any of Examples 13-19, and wherein the third resonator has a free spectral range between 200 gigahertz and 2,000 gigahertz.
Example 21 includes an integrated circuit component comprising the PIC die of any of Examples 13-20, further comprising an electronic integrated circuit (EIC) die mated with the PIC die; a plurality of solder balls positioned between the EIC die and the PIC die, wherein individual solder balls of the plurality of solder balls are adjacent individual contact pads of the plurality of contact pads of the PIC die; and a circuit board mated to the EIC die.
Example 22 includes a quantum cryptography system comprising the PIC die of any of Examples 13-21.
Example 23 includes the subject matter of Example 22, and further including a filter to remove light generated in the first resonator from a bus waveguide after the second resonator.
Example 24 includes the subject matter of any of Examples 22 and 23, and wherein there is no filter to remove light generated in the first resonator from a bus waveguide after the second resonator and before a third resonator.
Example 25 includes a LIDAR system comprising the PIC die of any of Examples 13-24.
Example 26 includes a photonic integrated circuit (PIC) die comprising means for generating first laser light, wherein the means for generating the first laser light has a gain bandwidth more than one terahertz; means for generating second laser light, wherein the means for generating the second laser light has a gain bandwidth less than 200 gigahertz, wherein the first laser light is to pump the means for generating the second laser light; and means for generating entangled photon pairs, wherein the means for generating entangled photon pairs is to pump the means for generating entangled photon pairs.
Example 27 includes the subject matter of Example 26, and wherein, in use, the means for generating second laser light is to pump the means for generating entangled photon pairs to create entangled photon pairs using spontaneous four-wave mixing.
Example 28 includes the subject matter of any of Examples 26 and 27, and wherein the means for generating entangled photon pairs acts as a spontaneous four-wave mixing (SFWM) source, wherein the SFWM has a signal-to-noise ratio of at least 1,000.
Example 29 includes the subject matter of any of Examples 26-28, and wherein the means for generating first laser light is a hybrid III-V/silicon semiconductor laser.
Example 30 includes the subject matter of any of Examples 26-29, and wherein the means for generating second laser light has a relative optical power of less than 70 dB at one nanometer away from a peak of the means for generating second laser light.
Example 31 includes the subject matter of any of Examples 26-30, and wherein the means for generating entangled photon pairs has a free spectral range between 200 gigahertz and 2,000 gigahertz.
Example 32 includes an integrated circuit component comprising the PIC die of any of Examples 26-31, further comprising an electronic integrated circuit (EIC) die mated with the PIC die; a plurality of solder balls positioned between the EIC die and the PIC die, wherein individual solder balls of the plurality of solder balls are adjacent individual contact pads of the plurality of contact pads of the PIC die; and a circuit board mated to the EIC die.
Example 33 includes a quantum cryptography system comprising the PIC die of any of Examples 26-32.
Example 34 includes the subject matter of Example 33, and further including a filter to remove light from the means for generating first laser light from a bus waveguide after the means for generating second laser light.
Example 35 includes the subject matter of any of Examples 33 and 34, and wherein there is no filter to remove light from the means for generating first laser light from a bus waveguide after the means for generating second laser light and before the means for generating entangled photon pairs.
Example 36 includes a LIDAR system comprising the PIC die of any of Examples 26-35.

1. A photonic integrated circuit (PIC) die comprising:
a semiconductor laser;
a Raman laser, wherein an output of the semiconductor laser is coupled to the Raman laser, wherein the semiconductor laser is to pump the Raman laser; and
a resonator, wherein an output of the Raman laser is coupled to the resonator.

2. The PIC die of claim 1, wherein, in use, the Raman laser is to pump the resonator to create entangled photon pairs using spontaneous four-wave mixing.

3. The PIC die of claim 1, wherein the resonator acts as a spontaneous four-wave mixing (SFWM) source, wherein the SFWM has a signal-to-noise ratio of at least 1,000.

4. The PIC die of claim 1, wherein the Raman laser is a silicon Raman laser, wherein the Raman laser has a gain bandwidth less than 200 gigahertz.

5. The PIC die of claim 1, wherein the semiconductor laser is a hybrid III-V/silicon semiconductor laser.

6. The PIC die of claim 1, wherein the Raman laser has an optical power of less than dB at one nanometer away from a peak of the Raman laser relative to optical power of the Raman laser at the peak of the Raman laser.

7. The PIC die of claim 1, wherein the resonator has a free spectral range greater than 200 gigahertz.

8. An integrated circuit component comprising the PIC die of claim 1, further comprising:
an electronic integrated circuit (EIC) die mated with the PIC die;
a plurality of solder balls positioned between the EIC die and the PIC die, wherein individual solder balls of the plurality of solder balls are adjacent individual contact pads of the plurality of contact pads of the PIC die; and
a circuit board mated to the EIC die.

9. A photonic integrated circuit (PIC) die comprising:
a first silicon waveguide forming a first resonator, the first silicon waveguide coupled to an amplifier region, wherein the first resonator is resonant at a first frequency;
a second silicon waveguide forming a second resonator, wherein the second resonator is resonant at the first frequency and at a second frequency, wherein the second frequency is a Raman shift away from the first frequency; and
one or more waveguides to couple light between the first resonator and the second resonator.

10. The PIC die of claim 9, further comprising:
a third silicon waveguide forming a third resonator, wherein the third resonator has a free spectral range greater than 200 gigahertz, wherein the third resonator is resonant with the second frequency,
wherein the one or more waveguides are to couple light between the second resonator and the third resonator.

11. The PIC die of claim 9, wherein the amplifier region comprises a III-V semiconductor.

12. The PIC die of claim 9, further comprising a third resonator, wherein, in use, the second resonator is to act as a Raman laser to pump the third resonator to create entangled photon pairs using spontaneous four-wave mixing.

13. The PIC die of claim 12, wherein the resonator acts as a spontaneous four-wave mixing (SFWM) source, wherein the SFWM has a signal-to-noise ratio of at least 1,000.

14. The PIC die of claim 12, wherein the Raman laser has a gain bandwidth less than 200 gigahertz.

15. The PIC die of claim 12, wherein the Raman laser has an optical power of less than 70 dB at one nanometer away from a peak of the Raman laser relative to an optical power at the peak of the Raman laser.

16. A quantum cryptography system comprising the PIC die of claim 9.

17. A photonic integrated circuit (PIC) die comprising:
means for generating first laser light, wherein the means for generating the first laser light has a gain bandwidth more than one terahertz;
means for generating second laser light, wherein the means for generating the second laser light has a gain bandwidth less than 200 gigahertz, wherein the first laser light is to pump the means for generating the second laser light; and
means for generating entangled photon pairs, wherein the means for generating entangled photon pairs is to pump the means for generating entangled photon pairs.

18. The PIC die of claim 17, wherein, in use, the means for generating second laser light is to pump the means for generating entangled photon pairs to create entangled photon pairs using spontaneous four-wave mixing.

19. The PIC die of claim 17, wherein the means for generating entangled photon pairs acts as a spontaneous four-wave mixing (SFWM) source, wherein the SFWM has a signal-to-noise ratio of at least 1,000.

20. The PIC die of claim 17, wherein the means for generating second laser light has a relative optical power of less than 70 dB at one nanometer away from a peak of the means for generating second laser light.
